(19) United States
(12) Patent Application Publication
(10) Pub. No.: US 2025/0349657 A1
(43) Pub. Date: Nov. 13, 2025

(54) CHIP PACKAGE STRUCTURE WITH LID AND METHOD FOR FORMING THE SAME

(71) Applicant: Taiwan Semiconductor Manufacturing Company, Ltd., Hsinchu (TW)

(72) Inventors: Kuan-Min Wang, Hsinchu City (TW); Chien-Chang Wang, Hsinchu City (TW); Ching Wang, Taichung City (TW); Kuo-Chin Chang, Chiayi City (TW); Kathy Wei Yan, Hsinchu (TW); Jun He, Zhubei City (TW)

(21) Appl. No.: 19/271,837

(22) Filed: Jul. 17, 2025

Related U.S. Application Data
(63) Continuation of application No. 18/644,209, filed on Apr. 24, 2024.
(60) Provisional application No. 63/611,978, filed on Dec. 19, 2023.

(51) Int. Cl. H01L 23/367; H01L 23/00

(52) U.S. Cl. CPC H01L 23/3675; H01L 24/29; H01L 24/30; H01L 24/32; H01L 24/33; H01L 24/13; H01L 24/16; H01L 24/73; H01L 2224/13082; H01L 2224/13111; H01L 2224/13124; H01L 2224/13147; H01L 2224/13184; H01L 2224/16225; H01L 2224/29011; H01L 2224/29013; H01L 2224/29105; H01L 2224/29109; H01L 2224/29111; H01L 2224/29113; H01L 2224/2919; H01L 2224/29191; H01L 2224/2929; H01L 2224/29291; H01L 2224/29386; H01L 2224/3003; H01L 2224/30051; H01L 2224/30505; H01L 2224/32225; H01L 2224/32245; H01L 2224/33181; H01L 2224/73204; H01L 2224/73253; H01L 2924/0542; H01L 2924/0543; H01L 2924/0665; H01L 2924/0715

(57) ABSTRACT

A chip package structure is provided. The chip package structure includes a carrier substrate. The chip package structure includes a chip structure over the carrier substrate. The chip structure includes a semiconductor substrate and a device layer, the semiconductor substrate has a front surface and a back surface opposite to the front surface, the front surface faces the carrier substrate, and the device layer is between the front surface and the carrier substrate. The chip package structure includes a heat dissipation lid over the back surface of the semiconductor substrate. The heat dissipation lid has a plate portion and a first protruding portion under the plate portion, and the first protruding portion extends into the semiconductor substrate from the back surface.

### REFERENCE TO RELATED APPLICATIONS

This application is a Continuation of U.S. application Ser. No. 18/644,209, filed on Apr. 24, 2024, which claims the benefit of U.S. Provisional Application No. 63/611,978, filed on Dec. 19, 2023. The contents of the above-referenced patent applications are hereby incorporated by reference in their entirety.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs.

In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A-1D are cross-sectional views of various stages of a process for forming a chip package structure, in accordance with some embodiments.

FIG. 1A-1 is an enlarged cross-sectional view illustrating a portion of the chip structure of FIG. 1A, in accordance with some embodiments.

FIG. 1A-2 is a top view of the chip structure of FIG. 1A, in accordance with some embodiments.

FIG. 1B-1 is an enlarged cross-sectional view illustrating a portion of the chip package structure of FIG. 1B, in accordance with some embodiments.

FIG. 1B-2 is a top view of the chip package structure of FIG. 1B, in accordance with some embodiments.

FIG. 1C-1 is a top view of the chip package structure of FIG. 1C, in accordance with some embodiments.

FIG. 1D-1 is a top view of the chip package structure of FIG. 1D, in accordance with some embodiments.

FIG. 2A is a cross-sectional view of a chip package structure, in accordance with some embodiments.

FIG. 2B is a top view of the chip package structure of FIG. 2A, in accordance with some embodiments.

FIG. 3A is a cross-sectional view of a chip package structure, in accordance with some embodiments.

FIG. 3B is a top view of the chip package structure of FIG. 3A, in accordance with some embodiments.

FIG. 4A is a cross-sectional view of a chip package structure, in accordance with some embodiments.

FIG. 4B is a top view of the chip package structure of FIG. 4A, in accordance with some embodiments.

FIGS. 5A-5B are cross-sectional views of various stages of a process for forming a chip package structure, in accordance with some embodiments.

FIGS. 6A-6B are cross-sectional views of various stages of a process for forming a chip package structure, in accordance with some embodiments.

FIG. 6A-1 is a top view of the chip package structure of FIG. 6A, in accordance with some embodiments.

FIG. 6B-1 is a top view of the chip package structure of FIG. 6B, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. The term “substantially” may be varied in different technologies and be in the deviation range understood by the skilled in the art. For example, the term “substantially” may also relate to 90% of what is specified or higher, such as 95% of what is specified or higher, especially 99% of what is specified or higher, including 100% of what is specified, though the present invention is not limited thereto. Furthermore, terms such as “substantially parallel” or “substantially perpendicular” may be interpreted as not to exclude insignificant deviation from the specified arrangement and may include for example deviations of up to 10°. The word “substantially” does not exclude “completely” e.g. a composition which is “substantially free” from Y may be completely free from Y.

The term “about” may be varied in different technologies and be in the deviation range understood by the skilled in the art. The term “about” in conjunction with a specific distance or size is to be interpreted so as not to exclude insignificant deviation from the specified distance or size. For example, the term “about” may include deviations of up to 10% of what is specified, though the present invention is not limited thereto. The term “about” in relation to a numerical value x may mean x±5 or 10% of what is specified, though the present invention is not limited thereto.

Some embodiments of the disclosure are described. Additional operations can be provided before, during, and/or after the stages described in these embodiments. Some of the stages that are described can be replaced or eliminated for different embodiments. Additional features can be added to the chip package structure. Some of the features described below can be replaced or eliminated for different embodiments. Although some embodiments are discussed with operations performed in a particular order, these operations may be performed in another logical order.

As the feature sizes of components (e.g., transistors, interconnect wires, etc.) within integrated chips continue to decrease, the integrated chips generate more heat. Integrated chip manufacturers have developed solutions to aid in the dissipation of such heat. Existing solutions are typically focused on uniform heat dissipation (e.g., dissipation of heat that is substantially homogeneous over a chip). However, it has been appreciated that different devices within an integrated chip may produce different amounts of heat. For example, high performance computing products (HPCs) may generate more heat than other devices within an integrated chip. The uneven generation of heat within an integrated chip leads to the formation of local hot spots. If heat is not efficiently dissipated from local hot spots, it can lead to performance degradation, reliability issues, and even chip failure.

The present disclosure relates to a chip package structure that is configured to improve heat dissipation from local hot spots of an integrated chip (e.g., from regions of a chip having high performance computing products). In some embodiments, the chip package structure comprises a chip structure disposed over a carrier substrate. The chip structure comprises a semiconductor substrate having a front surface and a back surface opposing the front surface. The front surface faces the carrier substrate. A device layer is between the front surface and the carrier substrate. A heat dissipation lid is disposed along the back surface of the semiconductor substrate. The heat dissipation lid has a plate portion and a protruding portion extending outward from the plate portion. The protruding portion extends from the back surface into the semiconductor substrate and towards a local hot spot within the device layer. Because the protruding portion is in close proximity to the local hot spot, the protruding portion is able to improve heat dissipation from the local hot spot.

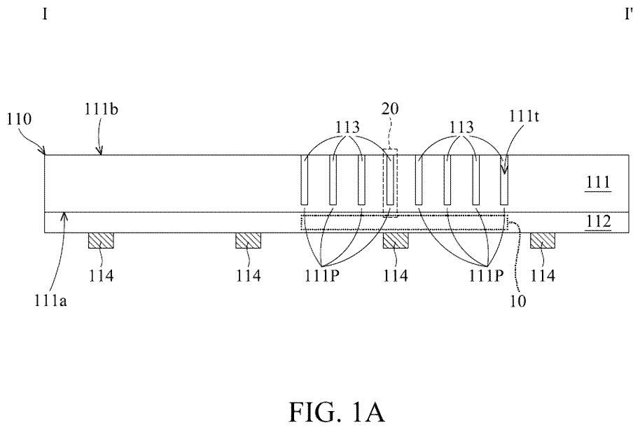

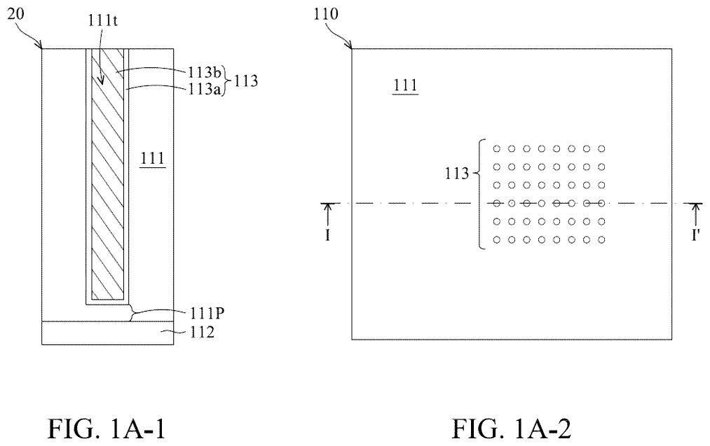

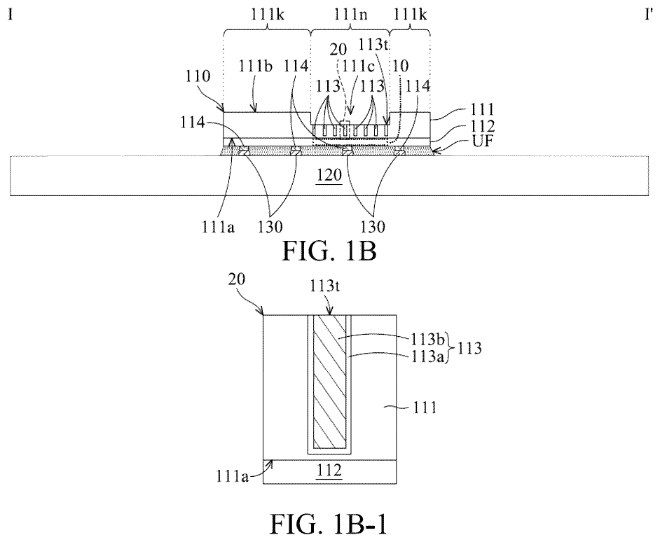

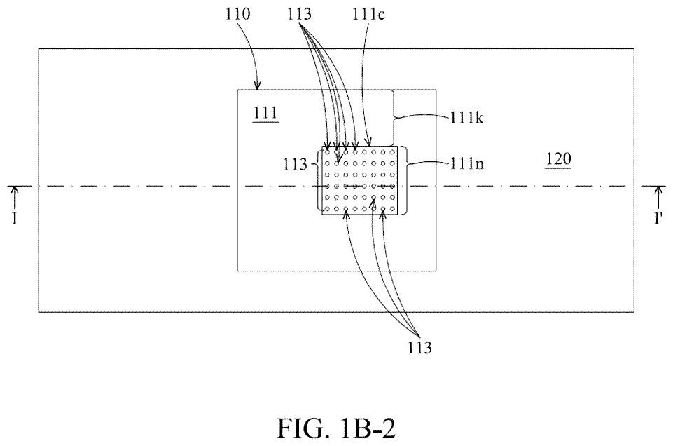

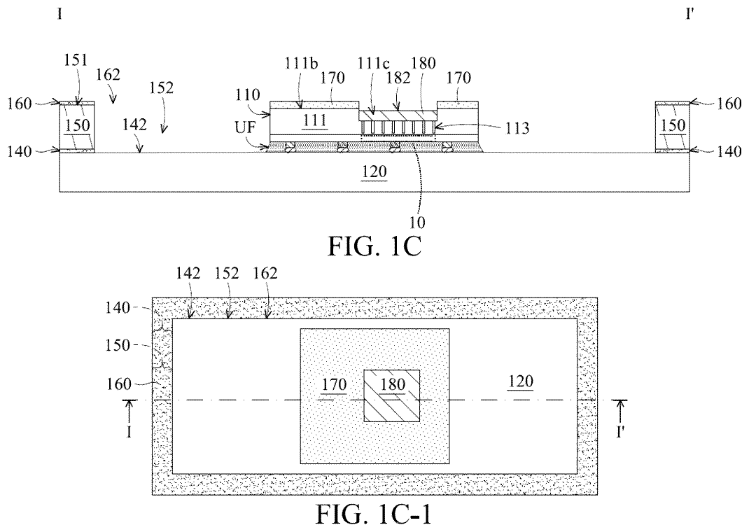

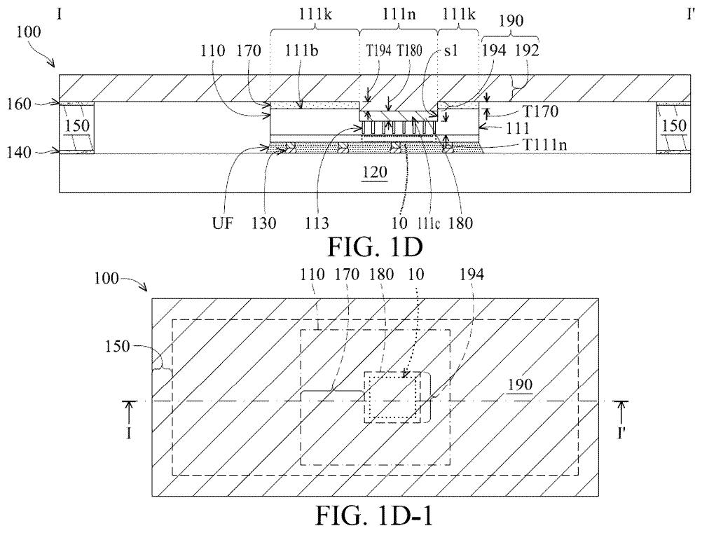

FIGS. 1A-1D are cross-sectional views of various stages of a process for forming a chip package structure, in accordance with some embodiments. As shown in FIG. 1A, a chip structure 110 is provided, in accordance with some embodiments. The chip structure 110 includes a semiconductor substrate 111, a device layer 112, heat conductive plugs 113, and conductive pillars 114, in accordance with some embodiments.

The semiconductor substrate 111 has a front surface 111a and a back surface 111b opposite to the front surface 111a, in accordance with some embodiments. The device layer 112 is formed over the front surface 111a, in accordance with some embodiments. The heat conductive plugs 113 are formed in the semiconductor substrate 111, in accordance with some embodiments. The conductive pillars 114 are formed over the device layer 112, in accordance with some embodiments.

The semiconductor substrate 111 includes, for example, a semiconductor wafer (such as a silicon wafer) or a portion of a semiconductor wafer. In some embodiments, the semiconductor substrate 111 is made of an elementary semiconductor material including silicon or germanium in a single crystal structure, a polycrystal structure, or an amorphous structure.

In some other embodiments, the semiconductor substrate 111 is made of a compound semiconductor, such as silicon carbide, gallium arsenide, gallium phosphide, indium phosphide, or indium arsenide, an alloy semiconductor, such as SiGe or GaAsP, or a combination thereof. The semiconductor substrate 111 may also include multi-layer semiconductors, semiconductor on insulator (SOI) (such as silicon on insulator or germanium on insulator), or a combination thereof.

In some embodiments, the device layer 112 includes various device elements and an interconnect structure (not shown). Examples of the various device elements include active devices, passive devices, other suitable elements, or a combination thereof. The active devices may include transistors or diodes (not shown) formed at the front surface 111a of the semiconductor substrate 111. The passive devices include resistors, capacitors, or other suitable passive devices, in accordance with some embodiments.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc. In various embodiments, the MOSFETs may include planar FETs, FinFETs, gate-all-around transistors (e.g., nanowire transistors), and/or the like.

Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the semiconductor substrate 111. The isolation features are used to surround active regions and electrically isolate various device elements formed in and/or over the semiconductor substrate 111 in the active regions. In some embodiments, the isolation features include shallow trench isolation (STI) features, local oxidation of silicon (LOCOS) features, other suitable isolation features, or a combination thereof.

The device layer 112 has a hot spot region 10, in accordance with some embodiments. The device elements in the hot spot region 10 include, for example, high-performance-computing (HPC) elements or other elements that tend to generate more heat, in accordance with some embodiments.

When the device elements of the device layer 112 operate, the temperature of the device layer 112 in the hot spot region 10 is higher than the temperature of the device layer 112 in other regions, in accordance with some embodiments.

In some embodiments, the interconnect structure of the device layer 112 includes a dielectric layer, wiring layers, conductive vias, and conductive pads, in accordance with some embodiments. The wiring layers, the conductive vias, and the conductive pads are in the dielectric layer, in accordance with some embodiments. The conductive vias are electrically connected between the wiring layers, between the wiring layer and the conductive pads, and between the wiring layer and the device elements, in accordance with some embodiments.

The dielectric layer is made of a dielectric material, such as an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer includes a low-k material or a porous dielectric material having a k-value which is lower than that of silicon oxide, or lower than about 3.0 or about 2.5, in accordance with some embodiments.

The dielectric layer is formed using a chemical vapor deposition (CVD) process, such as a low-pressure CVD process, a plasma-enhanced CVD process, or a high-density plasma CVD process, an atomic layer deposition process, a spin-on process, a physical vapor deposition process, or another suitable process.

The wiring layers, the conductive vias, and the conductive pads are made of conductive materials, such as metal (e.g., copper, aluminum, or tungsten) or alloys thereof, in accordance with some embodiments.

FIG. 1A-1 is an enlarged cross-sectional view illustrating a portion 20 of the chip structure 110 of FIG. 1A, in accordance with some embodiments. As shown in FIGS. 1A and 1A-1, the heat conductive plugs 113 do not pass through the semiconductor substrate 111, in accordance with some embodiments.

Portions 111P of the semiconductor substrate 111 are between the heat conductive plugs 113 and the device layer 112, in accordance with some embodiments. The thermal conductivity of the heat conductive plugs 113 is greater than the thermal conductivity of the semiconductor substrate 111, in accordance with some embodiments.

Each heat conductive plug 113 includes an insulating layer 113a and a conductive pillar 113b, in accordance with some embodiments. The insulating layer 113a is wrapped around the conductive pillar 113b, in accordance with some embodiments. The insulating layer 113a separates the conductive pillar 113b from the semiconductor substrate 111, in accordance with some embodiments.

The conductive pillars 113b are electrically insulated from the semiconductor substrate 111, in accordance with some embodiments. The insulating layer 113a separates the conductive pillar 113b from the device layer 112, in accordance with some embodiments. The conductive pillars 113b are electrically insulated from the device layer 112, in accordance with some embodiments.

The insulating layer 113a is made of a dielectric material, such as an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the insulating layer 113a includes a low-k material or a porous dielectric material having a k-value which is lower than that of silicon oxide, or lower than about 3.0 or about 2.5, in accordance with some embodiments. The conductive pillar 113b is made of conductive materials, such as metal (e.g., copper, aluminum, or tungsten) or alloys thereof, in accordance with some embodiments.

The formation of the heat conductive plugs 113 include: partially removing the semiconductor substrate 111 to form holes 111t in the semiconductor substrate 111; depositing an insulating material layer (not shown) over the back surface 111b of the semiconductor substrate 111 and in the holes 111t; forming a conductive layer (not shown) over the insulating material layer and in the holes 111t; and removing the conductive layer and the insulating material layer outside of the holes 111t, in accordance with some embodiments.

As shown in FIG. 1A-1, the insulating material layer remaining in the hole 111t forms the insulating layer 113a of the heat conductive plug 113, in accordance with some embodiments. The conductive layer remaining in the hole 111t forms the conductive pillar 113b of the heat conductive plug 113, in accordance with some embodiments.

The insulating material layer is formed using a chemical vapor deposition (CVD) process, such as a low-pressure CVD process, a plasma-enhanced CVD process, or a high-density plasma CVD process, an atomic layer deposition process, a physical vapor deposition process, or another suitable deposition process.

The conductive layer is formed using a plating process, such as an electroplating process, or a deposition process, such as a physical vapor deposition process, in accordance with some embodiments.

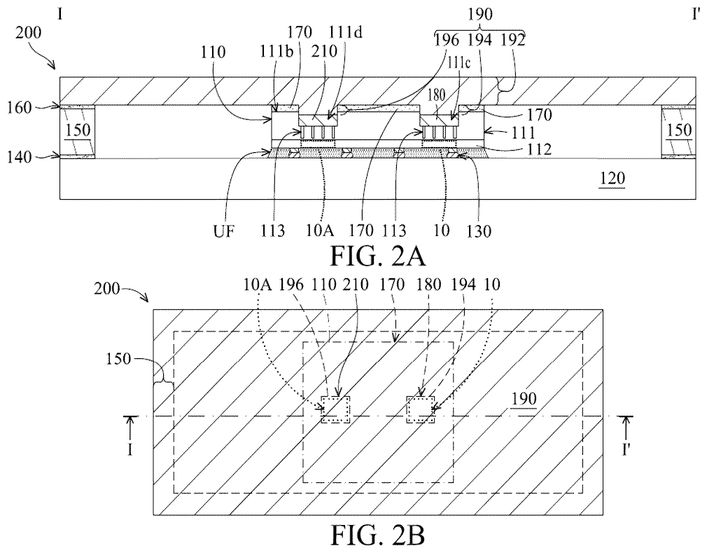

FIG. 1A-2 is a top view of the chip structure 110 of FIG. 1A, in accordance with some embodiments. FIG. 1A is a cross-sectional view illustrating the chip package structure along a sectional line I-I′ in FIG. 1A-2, in accordance with some embodiments. As shown in FIGS. 1A, 1A-1 and 1A-2, the heat conductive plugs 113 are arranged in an array (e.g., arranged in rows and columns with substantially equal spacing), in accordance with some embodiments. In some other embodiments (not shown), the heat conductive plugs 113 are arranged randomly (e.g., spaced at unequal distance with respect to one another).

As shown in FIG. 1A, the conductive pillars 114 are formed over the conductive pads of the device layer 112, in accordance with some embodiments. The conductive pillars 114 are electrically connected to the conductive pads, in accordance with some embodiments. The conductive pillars 114 are made of conductive materials, such as metal (e.g., copper, aluminum, or tungsten) or alloys thereof, in accordance with some embodiments.

FIG. 1B-1 is an enlarged cross-sectional view illustrating the portion 20 of the chip structure 110 of FIG. 1B, in accordance with some embodiments. FIG. 1B-2 is a top view of the chip package structure of FIG. 1B, in accordance with some embodiments. FIG. 1B is a cross-sectional view illustrating the chip package structure along a sectional line I-I′ in FIG. 1B-2, in accordance with some embodiments.

As shown in FIGS. 1B, 1B-1 and 1B-2, upper portions of the semiconductor substrate 111 and the heat conductive plugs 113 are removed to form a recess 111c in the semiconductor substrate 111, in accordance with some embodiments. The recess 111c is formed by sidewalls and a horizontally extending surface of the semiconductor substrate. The recess 111c exposes a top surface 113t of each heat conductive plug 113, in accordance with some embodiments. The heat conductive plugs 113 are under the recess 111c, in accordance with some embodiments.

As shown in FIGS. 1B and 1B-2, after the removal process, the semiconductor substrate 111 has a thick portion 111k and a thin portion 111n, in accordance with some embodiments. The thin portion 111n is under the recess 111c, in accordance with some embodiments. The thin portion 111n is thinner than the thick portion 111k, in accordance with some embodiments.

The thick portion 111k continuously surrounds the thin portion 111n, in accordance with some embodiments. The heat conductive plugs 113 penetrate into the thin portion 111n, in accordance with some embodiments. The removal process includes a photolithography process and an etching process, in accordance with some embodiments.

As shown in FIG. 1B, solder bumps 130 are formed on the conductive pillars 114, in accordance with some embodiments. The solder bumps 130 are made of tin (Sn) or another suitable conductive material with a melting point lower than that of the conductive pillars 114, in accordance with some embodiments. The solder bumps 130 are formed using a plating process such as an electroplating process, in accordance with some embodiments.

As shown in FIG. 1B, the chip structure 110 is bonded to a carrier substrate 120 (e.g., a wiring substrate) through the solder bumps 130, in accordance with some embodiments. The front surface 111a of the semiconductor substrate 111 faces the carrier substrate 120, in accordance with some embodiments. The device layer 112 is between the front surface 111a and the carrier substrate 120, in accordance with some embodiments.

The carrier substrate 120 includes a dielectric layer, conductive pads, wiring layers, and conductive vias (not shown), in accordance with some embodiments. The conductive pads are embedded in the dielectric layer, in accordance with some embodiments. The solder bumps 130 are bonded to the conductive pads of the carrier substrate 120, in accordance with some embodiments.

The wiring layers and the conductive vias of the carrier substrate 120 are formed in the dielectric layer of the carrier substrate 120, in accordance with some embodiments. The conductive vias are electrically connected between different wiring layers and between the wiring layer and the conductive pads, in accordance with some embodiments.

The dielectric layer is made of an insulating material such as a polymer material (e.g., polybenzoxazole or polyimide), nitride (e.g., silicon nitride), oxide (e.g., silicon oxide), silicon oxynitride, or the like, in accordance with some embodiments. The dielectric layer is formed using lamination process (or deposition processes), photolithography processes, and etching processes, in accordance with some embodiments.

The conductive pads are made of a conductive material, such as metal (e.g. copper, aluminum, or tungsten) or alloys thereof, in accordance with some embodiments. The wiring layers are made of a conductive material, such as metal (e.g. copper, aluminum, or tungsten) or alloys thereof, in accordance with some embodiments. The conductive vias are made of a conductive material, such as metal (e.g. copper, aluminum, or tungsten) or alloys thereof, in accordance with some embodiments.

In some embodiments, the conductive pads, the wiring layers, and the conductive vias are made of the same material. In some other embodiments. The conductive pads, the wiring layers, and the conductive vias are made of different materials.

As shown in FIG. 1B, an underfill layer UF is formed between the chip structure 110 and the carrier substrate 120, in accordance with some embodiments. The underfill layer UF surrounds the solder bumps 130 and the conductive pillars 114, in accordance with some embodiments. The underfill layer UF is made of an insulating material, such as a polymer material, in accordance with some embodiments.

FIG. 1C-1 is a top view of the chip package structure of FIG. 1C, in accordance with some embodiments. FIG. 1C is a cross-sectional view illustrating the chip package structure along a sectional line I-I′ in FIG. 1C-1, in accordance with some embodiments. As shown in FIGS. 1C and 1C-1, an adhesive layer 140 is formed over the carrier substrate 120, in accordance with some embodiments. The adhesive layer 140 has an opening 142, in accordance with some embodiments. The chip structure 110 is in the opening 142, in accordance with some embodiments.

The adhesive layer 140 is made of a polymer material such as epoxy or silicone, in accordance with some embodiments. The adhesive layer 140 is formed using a dispensing process, in accordance with some embodiments.

As shown in FIGS. 1C and 1C-1, a ring structure 150 is disposed over the adhesive layer 140, in accordance with some embodiments. The ring structure 150 has a top surface 151, in accordance with some embodiments. In some embodiments, the top surface 151 is higher than the back surface 111b of the semiconductor substrate 111. In some embodiments, the top surface 151 is substantially level with the back surface 111b of the semiconductor substrate 111. In some embodiments, the top surface 151 is lower than the back surface 111b of the semiconductor substrate 111.

The ring structure 150 has an opening 152 over the opening 142 of the adhesive layer 140, in accordance with some embodiments. The chip structure 110 is in the opening 152, in accordance with some embodiments.

The ring structure 150 is made of a rigid material, such as metal (e.g., copper or iron), alloys thereof (e.g., stainless steel), or another suitable material which is more rigid than the carrier substrate 120, in accordance with some embodiments.

As shown in FIGS. 1C and 1C-1, an adhesive layer 160 is formed over the ring structure 150, and a heat conductive layer 170 is formed over the back surface 111b of the semiconductor substrate 111, in accordance with some embodiments.

The adhesive layer 160 is made of a combination of polymer and metal (e.g., a silver paste) or a polymer (e.g., epoxy or silicone), in accordance with some embodiments. The adhesive layer 160 is formed using a dispensing process, in accordance with some embodiments.

The thermal conductivity of the heat conductive layer 170 is greater than the thermal conductivity of the semiconductor substrate 111, in accordance with some embodiments. The heat conductive layer 170 is made of a polymer material including silicone or epoxy, in accordance with some embodiments. The polymer material is doped with particles, which are made of aluminum oxide or zinc oxide, in accordance with some embodiments. The heat conductive layer 170 is formed using a dispensing process, in accordance with some embodiments.

As shown in FIGS. 1C and 1C-1, a heat conductive layer 180 is formed in the recess 111c of the semiconductor substrate 111, in accordance with some embodiments. The heat conductive layer 180 is in thermal contact with the semiconductor substrate 111 and the heat conductive plugs 113, in accordance with some embodiments. The heat conductive layer 180 is in direct contact with the semiconductor substrate 111 and the heat conductive plugs 113, in accordance with some embodiments.

The thermal conductivity of the heat conductive layer 180 is greater than the thermal conductivity of the semiconductor substrate 111, in accordance with some embodiments. The thermal conductivity of the heat conductive layer 180 is greater than the thermal conductivity of the heat conductive layer 170, in accordance with some embodiments.

As a result, the heat conductive layer 180 can quickly conduct the heat generated by the hot spot region 10 to a heat dissipation lid, which is subsequently bonded to the heat conductive layers 170 and 180, in accordance with some embodiments.

The adhesion of the heat conductive layer 170 to the semiconductor substrate 111 and the heat dissipation lid, which is subsequently bonded to the heat conductive layers 170 and 180, is greater than the adhesion of the heat conductive layer 180, in accordance with some embodiments. As a result, the heat conductive layer 170 can firmly fix the heat dissipation lid over the semiconductor substrate 111, in accordance with some embodiments.

The heat conductive layer 180 has a top surface 182, in accordance with some embodiments. The top surface 182 faces away from the carrier substrate 120, in accordance with some embodiments. The top surface 182 is lower than the back surface 111b of the semiconductor substrate 111, in accordance with some embodiments. In other embodiments, the top surface 182 may be substantially planar with or above the back surface 111b. In some such embodiments, the heat conductive layer 180 laterally contacts both the semiconductor substrate 111 and the heat conductive layer 170.

The heat conductive layers 170 and 180 are made of different materials, in accordance with some embodiments. In some embodiments, the heat conductive layer 180 is made of a solid material. In other embodiments, the heat conductive layer 180 is made of a liquid material at room temperature (e.g., at a temperature of between approximately 70 and approximately 100 degrees Fahrenheit). The heat conductive layer 180 is able to be a liquid material because the heat conductive layer 180 is disposed within a recess that is able to contain the liquid material.

The solid material includes tin (Sn), Indium (In), Bismuth (Bi), or alloys thereof, in accordance with some embodiments. The liquid material includes gallium (Ga), alloys thereof, or a resin material containing gallium (Ga) or alloys thereof, in accordance with some embodiments.

If the heat conductive layer 180 is made of the solid material, the heat conductive layer 180 is formed by disposing a metal sheet in the recess 111c, in accordance with some embodiments. The metal sheet may be slightly narrower than the recess 111c, in accordance with some embodiments. If the heat conductive layer 180 is made of the liquid material, the heat conductive layer 180 is formed using a dispensing process, in accordance with some embodiments.

FIG. 1D-1 is a top view of the chip package structure of FIG. 1D, in accordance with some embodiments. FIG. 1D is a cross-sectional view illustrating the chip package structure along a sectional line I-I′ in FIG. 1D-1, in accordance with some embodiments. As shown in FIGS. 1D and 1D-1, a heat dissipation lid 190 is bonded to the ring structure 150 and the semiconductor substrate 111 through the adhesive layer 160, the heat conductive layer 170, and the heat conductive layer 180, in accordance with some embodiments. In this step, a chip package structure 100 is substantially formed, in accordance with some embodiments.

The heat dissipation lid 190 has a plate portion 192 and a protruding portion 194, in accordance with some embodiments. The protruding portion 194 protrudes outward from a lower surface of the plate portion 192 to under the plate portion 192, in accordance with some embodiments. The plate portion 192 is over the back surface 111b of the semiconductor substrate 111, in accordance with some embodiments.

The plate portion 192 is over the heat conductive layer 170, in accordance with some embodiments. The heat conductive layer 170 is between the semiconductor substrate 111 and the plate portion 192 of the heat dissipation lid 190, in accordance with some embodiments.

The protruding portion 194 passes through the heat conductive layer 170, in accordance with some embodiments. The thickness T194 of the protruding portion 194 is greater than the thickness T170 of the heat conductive layer 170, in accordance with some embodiments. The protruding portion 194 extends into the semiconductor substrate 111 from the back surface 111b, in accordance with some embodiments.

The protruding portion 194 is partially in the recess 111c of the semiconductor substrate 111, in accordance with some embodiments. The protruding portion 194 is in contact with a sidewall of the heat conductive layer 170 and an inner wall s1 of the recess 111c of the semiconductor substrate 111, in accordance with some embodiments. If the heat conductive layer 180 is made of a liquid material, the protruding portion 194 can seal the heat conductive layer 180 in the recess 111c, in accordance with some embodiments.

The protruding portion 194 is over the heat conductive layer 180, in accordance with some embodiments. The protruding portion 194 is in thermal contact with the heat conductive layer 180, in accordance with some embodiments. The protruding portion 194 is in direct contact with the heat conductive layer 180, in accordance with some embodiments. The thickness T194 of the protruding portion 194 is greater than the thickness T180 of the heat conductive layer 180, in accordance with some embodiments.

The heat conductive layer 180 is between the semiconductor substrate 111 and the protruding portion 194, in accordance with some embodiments. The thickness T111n of the thin portion 111n of the semiconductor substrate 111 is greater than the thickness T180 of the heat conductive layer 180, in accordance with some embodiments. If the thickness T111n is less than the thickness T180, the thin portion 111n may be too thin and easily broken, in accordance with some embodiments.

The protruding portion 194 is over the thin portion 111n of the semiconductor substrate 111, in accordance with some embodiments. The heat conductive layer 180 is between the thin portion 111n and the protruding portion 194, in accordance with some embodiments.

The thermal conductivity of the heat dissipation lid 190 is greater than the thermal conductivity of the semiconductor substrate 111, in accordance with some embodiments. The thermal conductivity of the heat dissipation lid 190 is greater than the thermal conductivity of the heat conductive layer 180, in accordance with some embodiments.

The thermal conductivity of the heat dissipation lid 190 is greater than the thermal conductivity of the heat conductive layer 170, in accordance with some embodiments. The heat dissipation lid 190 with a high thermal conductivity has the protruding portion 194 close to the hot spot region 10 so as to quickly conduct the heat generated by the hot spot region 10, in accordance with some embodiments. By quickly conducting heat generated by the hot spot region 10, the protruding portion 194 of the heat dissipation lid 190 can expediate heat dissipation from the hot spot region 10 thereby accounting for non-uniform heat generation (e.g., by high performance computing products) at specific locations within the semiconductor substrate 111.

The heat conductive layer 180 and the heat conductive plugs 113, which have the thermal conductivity greater than that of the semiconductor substrate 111, are also close to the hot spot region 10, thereby further enhancing heat dissipation of hot spot regions. Therefore, the protruding portion 194, the heat conductive layer 180, and the heat conductive plugs 113 can improve the heat dissipation efficiency of the chip package structure 100, in accordance with some embodiments.

The heat dissipation lid 190 is made of a high thermal conductivity material, such as a metal material (aluminum or copper), an alloy material (e.g., stainless steel), or aluminum-silicon carbide (AlSiC), in accordance with some embodiments.

The bonding process includes an annealing process, in accordance with some embodiments. During the annealing process, the adhesive layers 140 and 160 and the heat conductive layer 170 are cured, in accordance with some embodiments. If the heat conductive layer 180 is made of a solid material (e.g., a metal sheet), the solid material is reflowed to fit the shape of the recess 111c during the annealing process, in accordance with some embodiments. As shown in FIG. 1D-1, the protruding portion 194 has a square shape, in accordance with some embodiments.

FIG. 2A is a cross-sectional view of a chip package structure 200, in accordance with some embodiments. FIG. 2B is a top view of the chip package structure 200 of FIG. 2A, in accordance with some embodiments. FIG. 2A is a cross-sectional view illustrating the chip package structure 200 along a sectional line I-I′ in FIG. 2B, in accordance with some embodiments.

As shown in FIGS. 2A and 2B, the chip package structure 200 is similar to the chip package structure 100 of FIG. 1D, except that the heat dissipation lid 190 further has a protruding portion 196 and chip package structure 200 further includes a heat conductive layer 210, in accordance with some embodiments. The device layer 112 further has a hot spot region 10A, in accordance with some embodiments.

The protruding portion 196 is under the plate portion 192, in accordance with some embodiments. The protruding portion 196 is spaced apart from the protruding portion 194, in accordance with some embodiments. The protruding portion 196 is over the hot spot region 10A, in accordance with some embodiments.

The protruding portion 196 passes through the heat conductive layer 170, in accordance with some embodiments. The protruding portion 196 extends into the semiconductor substrate 111 from the back surface 111b, in accordance with some embodiments.

The heat conductive layer 210 is in a recess 111d of the semiconductor substrate 111, in accordance with some embodiments. The protruding portion 196 is partially in the recess 111d, in accordance with some embodiments. The protruding portion 196 is in thermal contact with the heat conductive layer 210, in accordance with some embodiments. The protruding portion 196 is in direct contact with the heat conductive layer 210, in accordance with some embodiments. As shown in FIG. 2B, the protruding portion 196 has a square shape, in accordance with some embodiments.

It will be appreciated that although FIGS. 2A-2B illustrate a semiconductor substrate 111 having two hot spot regions, that the disclosed chip package structure is not limited to having two protruding portions that enhance heat dissipation within two hot spot regions. Rather, the disclosed chip package structure may have additional protruding portions that enhance heat dissipation within additional hot spot regions.

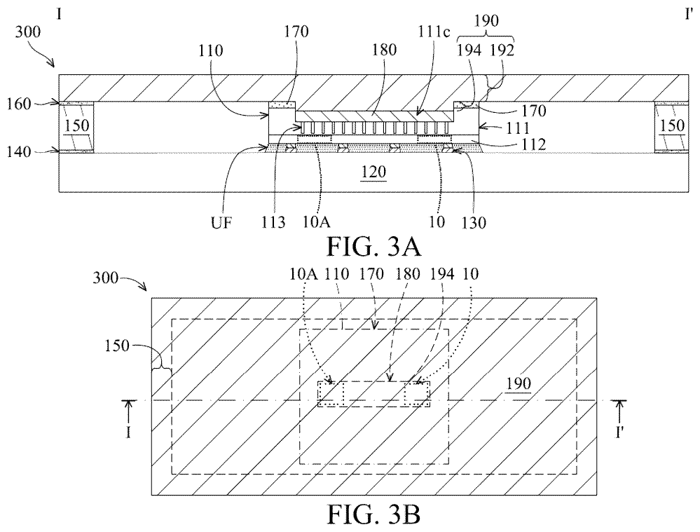

FIG. 3A is a cross-sectional view of a chip package structure 300, in accordance with some embodiments. FIG. 3B is a top view of the chip package structure 300 of FIG. 3A, in accordance with some embodiments. FIG. 3A is a cross-sectional view illustrating the chip package structure 300 along a sectional line I-I′ in FIG. 3B, in accordance with some embodiments.

As shown in FIGS. 3A and 3B, the chip package structure 300 is similar to the chip package structure 200 of FIGS. 2A and 2B, except that the protruding portion 194 extends across the hot spot regions 10 and 10A of the device layer 112, in accordance with some embodiments. As shown in FIG. 3B, the protruding portion 194 has a strip shape, in accordance with some embodiments. In some embodiments (not shown), the heat conductive plugs 113 may be arranged within arrays that are above hot spot regions 10 and 10A and that are separated from one another by a distance that is larger than a spacing between heat conductive plugs within an array.

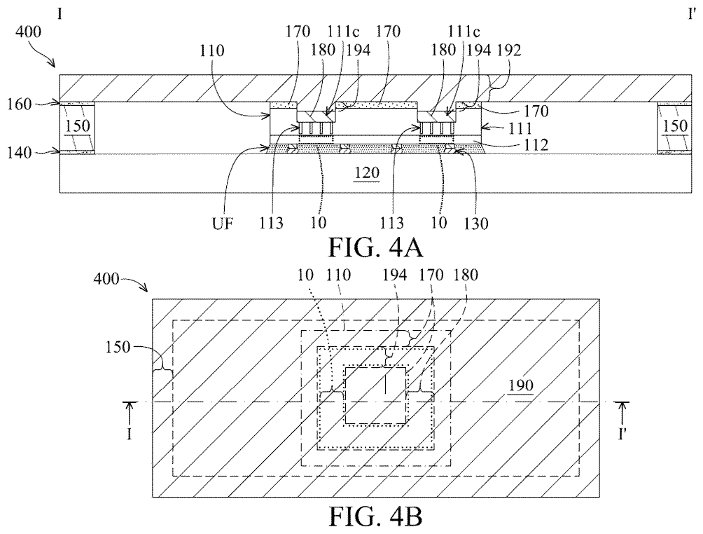

FIG. 4A is a cross-sectional view of a chip package structure 400, in accordance with some embodiments. FIG. 4B is a top view of the chip package structure 400 of FIG. 4A, in accordance with some embodiments. FIG. 4A is a cross-sectional view illustrating the chip package structure 400 along a sectional line I-I′ in FIG. 4B, in accordance with some embodiments. As shown in FIGS. 4A and 4B, the chip package structure 400 is similar to the chip package structure 200 of FIGS. 2A and 2B, except that the protruding portion 194 and the hot spot region 10 have a ring shape, in accordance with some embodiments.

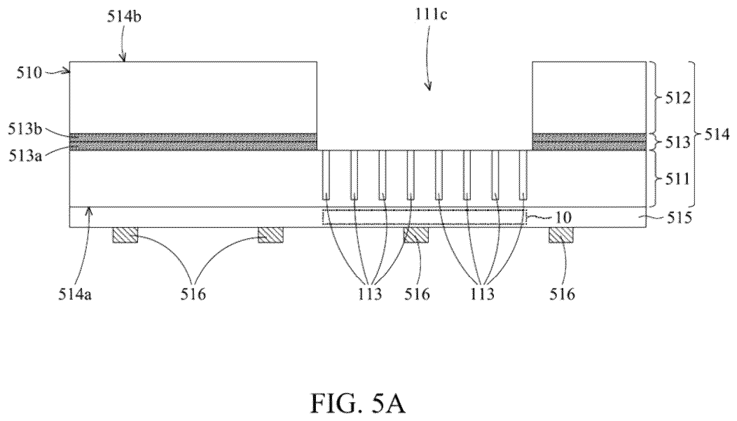

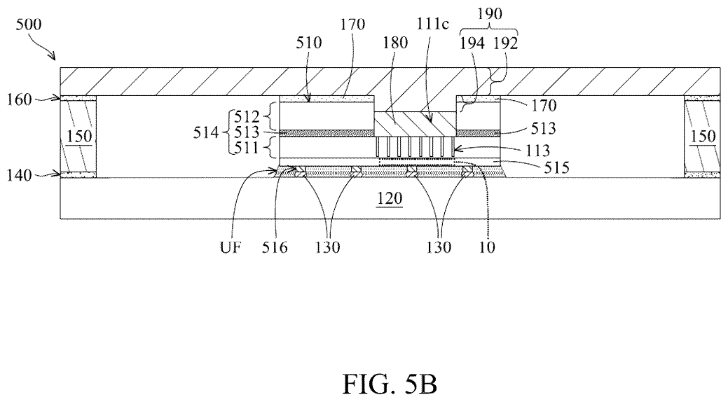

FIGS. 5A-5B are cross-sectional views of various stages of a process for forming a chip package structure 500, in accordance with some embodiments. As shown in FIG. 5A, a chip structure 510 is provided, in accordance with some embodiments. The chip structure 510 includes a substrate 514, a device layer 515, heat conductive plugs 113, and conductive pillars 516, in accordance with some embodiments.

The substrate 514 has a front surface 514a and a back surface 514b opposite to the front surface 514a, in accordance with some embodiments. The device layer 515 is formed over the front surface 514a, in accordance with some embodiments. The heat conductive plugs 113 are formed in the substrate 514, in accordance with some embodiments. The conductive pillars 516 are formed over the device layer 515, in accordance with some embodiments.

The substrate 514 includes a lower semiconductor layer 511, an upper semiconductor layer 512, and a bonding layer 513, in accordance with some embodiments. The bonding layer 513 is between the lower semiconductor layer 511 and the upper semiconductor layer 512, in accordance with some embodiments.

The lower semiconductor layer 511 or the upper semiconductor layer 512 includes, for example, a semiconductor wafer (such as a silicon wafer) or a portion of a semiconductor wafer. In some embodiments, the lower semiconductor layer 511 and the upper semiconductor layer 512 are made of an elementary semiconductor material including silicon or germanium in a single crystal structure, a polycrystal structure, or an amorphous structure.

In some other embodiments, the lower semiconductor layer 511 and the upper semiconductor layer 512 are made of a compound semiconductor, such as silicon carbide, gallium arsenide, gallium phosphide, indium phosphide, or indium arsenide, an alloy semiconductor, such as SiGe or GaAsP, or a combination thereof. The bonding layer 513 is made of an oxide-containing material (e.g., silicon oxide), in accordance with some embodiments.

The formation of the substrate 514 and the heat conductive plugs 113 includes: providing the lower semiconductor layer 511 and a dielectric layer 513a (e.g., an oxide layer) over the lower semiconductor layer 511; providing the upper semiconductor layer 512 and an dielectric layer 513b (e.g., an oxide layer) over the upper semiconductor layer 512; bonding the upper semiconductor layer 512 to the lower semiconductor layer 511 through the dielectric layers 513b and 513a; forming the heat conductive plugs 113 in the substrate 514; and partially removing the upper semiconductor layer 512, the bonding layer 513, and the heat conductive plugs 113 in the upper semiconductor layer 512 and the bonding layer 513 to form a recess 111c in the substrate 514, in accordance with some embodiments.

The dielectric layers 513a and 513b together form the bonding layer 513, in accordance with some embodiments. The bonding process for bonding the dielectric layers 513a and 513b includes an oxide fusion bonding process, in accordance with some embodiments.

In some embodiments, the device layer 515 includes various device elements and an interconnect structure (not shown). Examples of the various device elements include active devices, passive devices, other suitable elements, or a combination thereof. The active devices may include transistors or diodes (not shown) formed at the front surface 514a of the substrate 514. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the lower semiconductor layer 511. The isolation features are used to surround active regions and electrically isolate various device elements formed in and/or over the lower semiconductor layer 511 in the active regions. In some embodiments, the isolation features include shallow trench isolation (STI) features, local oxidation of silicon (LOCOS) features, other suitable isolation features, or a combination thereof.

The device layer 515 has a hot spot region 10, in accordance with some embodiments. The device elements in the hot spot region 10 include, for example, high-performance-computing (HPC) elements or other elements that tend to generate more heat, in accordance with some embodiments.

When the device elements of the device layer 515 operate, the temperature of the device layer 515 in the hot spot region 10 is higher than the temperature of the device layer 515 in other regions, in accordance with some embodiments.

In some embodiments, the interconnect structure of the device layer 515 includes a dielectric layer, wiring layers, conductive vias, and conductive pads, in accordance with some embodiments. The wiring layers, the conductive vias, and the conductive pads are in the dielectric layer, in accordance with some embodiments.

The conductive vias are electrically connected between the wiring layers, between the wiring layer and the conductive pads, and between the wiring layer and the device elements, in accordance with some embodiments.

The dielectric layer is made of a dielectric material, such as an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer includes a low-k material or a porous dielectric material having a k-value which is lower than that of silicon oxide, or lower than about 3.0 or about 2.5, in accordance with some embodiments.

The dielectric layer is formed using a chemical vapor deposition (CVD) process, such as a low-pressure CVD process, a plasma-enhanced CVD process, or a high-density plasma CVD process, an atomic layer deposition process, a spin-on process, a physical vapor deposition process, or another suitable process.

The wiring layers, the conductive vias, and the conductive pads are made of conductive materials, such as metal (e.g., copper, aluminum, or tungsten) or alloys thereof, in accordance with some embodiments.

The conductive pillars 516 are formed over the conductive pads of the device layer 515, in accordance with some embodiments. The conductive pillars 516 are electrically connected to the conductive pads, in accordance with some embodiments. The conductive pillars 516 are made of conductive materials, such as metal (e.g., copper, aluminum, or tungsten) or alloys thereof, in accordance with some embodiments.

As shown in FIG. 5B, the steps of FIGS. 1B-1D are performed to form the carrier substrate 120, the solder bumps 130, the adhesive layer 140, the ring structure 150, the adhesive layer 160, the heat conductive layer 170, the heat conductive layer 180, and the heat dissipation lid 190, in accordance with some embodiments. In this step, a chip package structure 500 is substantially formed, in accordance with some embodiments.

The heat conductive layer 180 is formed in the recess 111c, in accordance with some embodiments. The heat conductive layer 180 is in the upper semiconductor layer 512 and passes through the bonding layer 513, in accordance with some embodiments. The heat conductive layer 180 is in thermal contact with the lower semiconductor layer 511, the upper semiconductor layer 512, and the bonding layer 513, in accordance with some embodiments. The heat conductive layer 180 is in direct contact with the lower semiconductor layer 511, the upper semiconductor layer 512, and the bonding layer 513, in accordance with some embodiments.

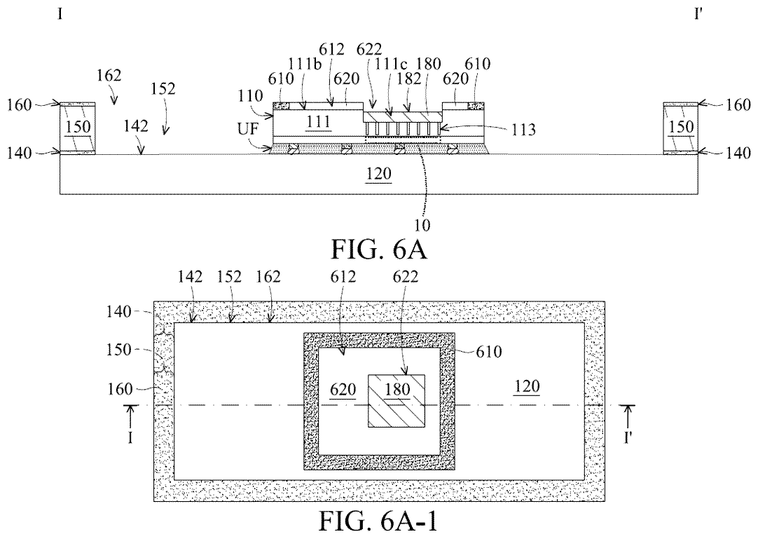

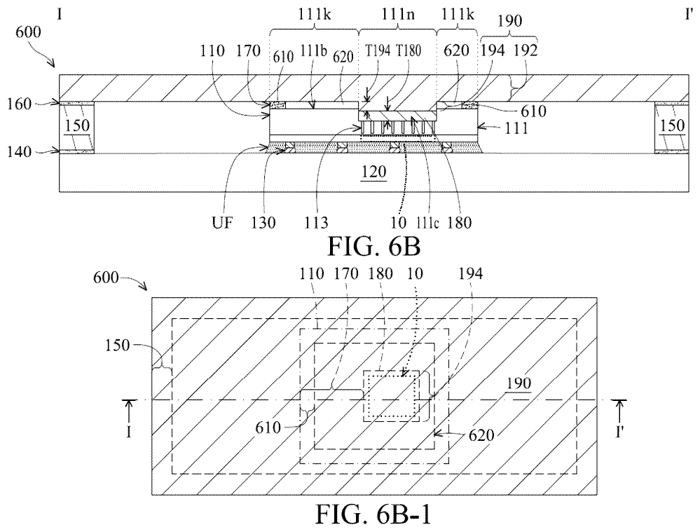

FIGS. 6A-6B are cross-sectional views of various stages of a process for forming a chip package structure, in accordance with some embodiments. FIG. 6A-1 is a top view of the chip package structure of FIG. 6A, in accordance with some embodiments. FIG. 6A is a cross-sectional view illustrating the chip package structure along a sectional line I-I′ in FIG. 6A-1, in accordance with some embodiments.

After the step of FIG. 1B, as shown in FIGS. 6A and 6A-1, an adhesive layer 160 is formed over the ring structure 150, and an adhesive layer 610 is formed over the back surface 111b of the semiconductor substrate 111, in accordance with some embodiments.

The adhesive layer 610 has a ring shape, in accordance with some embodiments. The adhesive layer 610 has an opening 612, in accordance with some embodiments. The opening 612 exposes a portion of the back surface 111b of the semiconductor substrate 111, in accordance with some embodiments.

The adhesive layer 610 is made of a combination of polymer and metal (e.g., a silver paste) or a polymer (e.g., epoxy or silicone), in accordance with some embodiments. The adhesive layer 610 is formed using a dispensing process, in accordance with some embodiments.

As shown in FIGS. 6A and 6A-1, a heat conductive layer 620 is formed in the opening 612 of the adhesive layer 610 and over the back surface 111b of the semiconductor substrate 111, in accordance with some embodiments. The heat conductive layer 620 has a ring shape, in accordance with some embodiments.

The heat conductive layer 620 has an opening 622 over the recess 111c of the semiconductor substrate 111, in accordance with some embodiments. The heat conductive layer 620 is made of graphite or a polymer material doped with carbon fillers, in accordance with some embodiments.

As shown in FIGS. 6A and 6A-1, a heat conductive layer 180 is formed in the recess 111c of the semiconductor substrate 111, in accordance with some embodiments.

FIG. 6B-1 is a top view of the chip package structure of FIG. 6B, in accordance with some embodiments. FIG. 6B is a cross-sectional view illustrating the chip package structure along a sectional line I-I′ in FIG. 6B-1, in accordance with some embodiments.

As shown in FIGS. 6B and 6B-1, a heat dissipation lid 190 is bonded to the ring structure 150 and the semiconductor substrate 111 through the adhesive layers 160 and 610, the heat conductive layer 620, and the heat conductive layer 180, in accordance with some embodiments. In this step, a chip package structure 600 is substantially formed, in accordance with some embodiments.

The thermal conductivity of the heat conductive layer 620 is greater than the thermal conductivity of the adhesive layer 610, in accordance with some embodiments. The adhesion of the adhesive layer 610 to the semiconductor substrate 111 and the heat dissipation lid 190 is greater than the adhesion of the heat conductive layer 620, in accordance with some embodiments.

Processes and materials for forming the chip package structures 200, 300, 400, 500 and 600 may be similar to, or the same as, those for forming the chip package structure 100 described above. Elements designated by the same or similar reference numbers as those in FIGS. 1A to 6B-1 have the same or similar structures and the materials. Therefore, the detailed descriptions thereof will not be repeated herein.

In accordance with some embodiments, chip package structures and methods for forming the same are provided. The methods (for forming the chip package structure) form a heat dissipation lid having a protruding portion extending toward a hot spot region of a device layer. Since the protruding portion is close to the hot spot region, the protruding portion can quickly conduct the heat generated by the hot spot region.

The methods (for forming the chip package structure) further form a heat conductive layer in a substrate of a chip structure and under the protruding portion, and the heat conductive layer is close to the hot spot region. Therefore, the heat conductive layer can quickly conduct the heat generated by the hot spot region to the heat dissipation lid. As a result, the heat dissipation efficiency of the chip package structure is improved.

In accordance with some embodiments, a chip package structure is provided. The chip package structure includes a carrier substrate. The chip package structure includes a chip structure over the carrier substrate. The chip structure includes a semiconductor substrate and a device layer, the semiconductor substrate has a front surface and a back surface opposite to the front surface, the front surface faces the carrier substrate, and the device layer is between the front surface and the carrier substrate. The chip package structure includes a heat dissipation lid over the back surface of the semiconductor substrate. The heat dissipation lid has a plate portion and a first protruding portion under the plate portion, and the first protruding portion extends into the semiconductor substrate from the back surface.

In accordance with some embodiments, a chip package structure is provided. The chip package structure includes a carrier substrate. The chip package structure includes a chip structure on the carrier substrate. The chip structure includes a substrate and a device layer arranged along a front surface of the substrate that faces the carrier substrate, the substrate has sidewalls that form a recess along a back surface of the substrate opposing the front surface. The chip package structure includes a heat conductive layer disposed between the sidewalls of the substrate. A first thermal conductivity of the heat conductive layer is greater than a second thermal conductivity of the substrate. The chip package structure includes a heat dissipation lid over the back surface of the substrate and the heat conductive layer. The heat dissipation lid includes a protrusion that extends outward from a lower surface of the heat dissipation lid towards the heat conductive layer.

In accordance with some embodiments, a method for forming a chip package structure is provided. The method includes forming a chip structure to have a device layer arranged along a front surface of a substrate, the device layer having a hot spot region; etching a back surface of the substrate to form a recess over the hot spot region; bonding the front surface of the chip structure to a carrier substrate. The method includes bonding a heat dissipation lid to the back surface of the substrate. The heat dissipation lid has a plate portion and a protruding portion under the plate portion, the plate portion is over the back surface of the substrate, and the protruding portion is in the recess of the back surface of the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1-20. (canceled)

21. An integrated chip structure, comprising:
a substrate;
an integrated chip disposed on the substrate, wherein the integrated chip comprises one or more devices and a plurality of interconnects arranged on a semiconductor body;
a thermal interface layer embedded in the integrated chip; and
a lid covering the integrated chip and the thermal interface layer, wherein the lid has a protrusion structure extending into the integrated chip directly over the thermal interface layer.

22. The integrated chip structure of claim 21, further comprising:
a plurality of heat conductive plugs arranged within the semiconductor body at a location that is directly below the thermal interface layer.

23. The integrated chip structure of claim 22, wherein the plurality of heat conductive plugs are arranged in an array.

24. The integrated chip structure of claim 21, wherein the thermal interface layer is arranged along a back-side of the semiconductor body that faces away from the plurality of interconnects.

25. The integrated chip structure of claim 21, further comprising:
a second thermal interface layer arranged on the semiconductor body and laterally outside of the thermal interface layer, the second thermal interface layer vertically separating an upper surface of the semiconductor body from a lower surface of the lid.

26. The integrated chip structure of claim 25, wherein the lid continuously extends from over a top of the second thermal interface layer to along a sidewall of the second thermal interface layer.

27. The integrated chip structure of claim 21, further comprising:
a plurality of conductive bonding structures arranged vertically between the substrate and the integrated chip; and
an underfill layer arranged vertically between the substrate and the integrated chip and laterally surrounding the plurality of conductive bonding structures.

28. An integrated chip structure, comprising:
a substrate;
an integrated chip arranged on the substrate, wherein the integrated chip comprises a first side facing the substrate and a second side facing away from the substrate, the integrated chip having sidewalls that form a recess within the second side of the substrate;
a thermal interface material disposed in the recess and along the sidewalls of the integrated chip; and
a lid coupled to the substrate and covering the integrated chip and the thermal interface material.

29. The integrated chip structure of claim 28, further comprising:
a plurality of heat conductive plugs extending within the integrated chip, wherein the plurality of heat conductive plugs contact a lower surface of the thermal interface material facing the substrate.

30. The integrated chip structure of claim 28, wherein the integrated chip comprises:
a lower semiconductor layer;
an upper semiconductor layer; and
a dielectric structure arranged between the lower semiconductor layer and the upper semiconductor layer.

31. The integrated chip structure of claim 30, wherein the thermal interface material is arranged along sidewalls of the upper semiconductor layer and the dielectric structure.

32. The integrated chip structure of claim 31, wherein the lid is arranged along the sidewalls of the upper semiconductor layer.

33. The integrated chip structure of claim 31, further comprising:
a plurality of conductive vias arranged within the lower semiconductor layer, wherein the thermal interface material extends through the upper semiconductor layer and the dielectric structure to contact the plurality of conductive vias.

34. The integrated chip structure of claim 31, wherein the thermal interface material comprises a liquid material at room temperature.

35. The integrated chip structure of claim 31, wherein the thermal interface material comprises one or more of tin, indium, and bismuth.

36. An integrated chip structure, comprising:
a substrate;
an integrated chip (IC) die arranged on the substrate;
a lid covering the IC die, wherein the lid comprises sidewalls that extend outward from a lower surface of the lid to form a protrusion over the IC die; and
wherein the IC die extends past the sidewalls of the lid that form the protrusion along a first direction and along a second direction in a sectional top-view, the first direction being perpendicular to the second direction.

37. The integrated chip structure of claim 36, wherein the protrusion has a rectangular shape in the sectional top-view.

38. The integrated chip structure of claim 36, wherein the protrusion has a ring shape in the sectional top-view.

39. The integrated chip structure of claim 36, further comprising:
a first thermal interface material along interior sidewalls of the IC die; and
a second thermal interface material arranged between an upper surface of the IC die and the lower surface of the lid, wherein the first thermal interface material and the second thermal interface material comprise different materials.

40. The integrated chip structure of claim 39,
wherein the first thermal interface material comprises tin, indium, bismuth, a liquid material including gallium, or a resin material containing gallium; and
wherein the second thermal interface material comprises a polymer material doped with particles of aluminum oxide or zinc oxide.
